(19) United States
(12) Patent Application Publication
(10) Pub. No.: US 2026/0090376 A1
(43) Pub. Date: Mar. 26, 2026

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Shih-Ping CHANG, Taichung City (TW); Liang-Pin CHEN, Taichung City (TW)

(73) Assignee: SILICONWARE PRECISION INDUSTRIES CO., LTD., Taichung City (TW)

(21) Appl. No.: 19/003,609

(22) Filed: Dec. 27, 2024

(30) Foreign Application Priority Data
Sep. 25, 2024 (TW) 113136444

(51) Int. Cl. H01L 23/367; H01L 21/48; H01L 23/00; H01L 23/498; H01L 25/16

(52) U.S. Cl. CPC H10W 40/226; H10W 70/023; H10W 70/65; H10W 70/66; H10W 90/00; H10W 72/252; H10W 72/877; H10W 74/15; H10W 90/724; H10W 90/734

(57) ABSTRACT

An electronic package is provided. A package module and a semiconductor chip are disposed on a carrier structure, and a laminating member is disposed on the semiconductor chip and the package module. A heat dissipating member is then disposed on the carrier structure and the laminating member. Therefore, by arranging the laminating member, the stress of the carrier structure can be evenly distributed to prevent the problem of delamination from occurring to the semiconductor chip. A manufacturing method of the electronic package is also provided.

### BACKGROUND

### 1. Technical Field

The present disclosure relates to a semiconductor packaging technology, and more particularly, to an electronic package that can improve reliability and a manufacturing method thereof.

### 2. Description of Related Art

To ensure the continuation of miniaturization and multi-functionality of electronic products and communication devices, semiconductor packages must evolve toward miniaturization to enable the interconnection of numerous pins and provide fast operation and high functionality. For instance, in the advanced packaging process, a common type of packaging is fan-out wiring with embedded components, etc.

In addition, with the booming development of the electronics industry, electronic products are gradually moving toward the trend of multifunctionality and high performance. The current fifth-generation (5G) communication technology applications have been extended to the internet of things (IoT), industrial internet of things (IIoT), cloud, artificial intelligence (AI), autonomous car, medical and other fields. Further, with the expansion of the application level, a very large amount of data needs to be efficiently transmitted, computed and stored. In particular, the demand for data transmission has emerged in large numbers, causing the industry to begin to use “light” instead of “electricity” as a data transmission carrier so as to improve the transmission capacity, efficiency, or distance and to reduce the energy consumption in the transmission process. In this context, co-packaged optics have become the future trend of semiconductor and packaging technology.

FIG. 1A is a schematic cross-sectional view showing a conventional semiconductor package 1. As shown in FIG. 1A, in the semiconductor package 1, a package module 1a and at least one semiconductor chip 11 are disposed on an upper side 10a of a carrier structure 10, and a heat dissipating member 15 is positioned over the upper side 10a of the carrier structure 10 and is disposed on the package module 1a and the semiconductor chip 11 via a heat dissipating layer 150. Additionally, at least one functional chip 12 is disposed on a lower side 10b of the carrier structure 10. The package module 1a is, for example, an optical module or an optical engine.

However, in a manufacturing method of the conventional semiconductor package 1, the height of the package module 1a is not the same as the height of the semiconductor chip 11, i.e., the package module 1a is higher than the semiconductor chip 11, which results in the problem of the semiconductor chip 11 being easily delaminated due to the uneven thermal stress in the subsequent thermal process.

Furthermore, when the heat dissipating member 15 is laminated to the package module 1a and the semiconductor chip 11, the height of the package module 1a is not the same as the height of the semiconductor chip 11, which results in an inconsistency in the pressure borne by the carrier structure 10, leading to a break in the carrier structure 10 (i.e., a crack K as shown in FIG. 1B), or even a crack in the functional chip 12 on the lower side 10b.

Therefore, how to overcome the above-mentioned problems of the prior art has become an urgent issue for the industry to solve.

### SUMMARY

In view of the various deficiencies of the prior art, the present disclosure provides an electronic package, which comprises: a carrier structure having a first side and a second side opposite to the first side; a package module disposed on the first side of the carrier structure and electrically connected to the carrier structure; a semiconductor chip disposed on the first side of the carrier structure and electrically connected to the carrier structure; a laminating member disposed on the semiconductor chip and the package module; and a heat dissipating member disposed on the first side of the carrier structure and on the laminating member.

The present disclosure provides a method of manufacturing an electronic package, the method comprises: providing a carrier structure having a first side and a second side opposite to the first side; disposing a package module and a semiconductor chip on the first side of the carrier structure and electrically connecting the package module and the semiconductor chip to the carrier structure; disposing a laminating member on the semiconductor chip and the package module; and disposing a heat dissipating member on the first side of the carrier structure and on the laminating member.

In the aforementioned electronic package and method, the laminating member is a glass structure or a mesh structure.

In the aforementioned electronic package and method, the laminating member is a platform structure.

In the aforementioned electronic package and method, the laminating member is bonded to the semiconductor chip and the package module via a heat dissipating layer.

In the aforementioned electronic package and method, the heat dissipating member is bonded to the laminating member via a heat dissipating layer.

In the aforementioned electronic package and method, the heat dissipating member has a heat dissipating body and a supporting leg connecting to the heat dissipating body, the heat dissipating body is bonded to the laminating member via a heat dissipating layer, and the supporting leg is bonded to the first side of the carrier structure via an adhesive material.

In the aforementioned electronic package and method, the present disclosure further comprises disposing a functional chip on the second side of the carrier structure.

In the aforementioned electronic package and method, the present disclosure further comprises disposing a functional member on the first side of the carrier structure and connecting the functional member to the laminating member. The functional member is, for example, a pillar or a heat dissipater.

In summary, the electronic package of the present disclosure and the manufacturing method thereof are configured to disperse the stress of the carrier structure by the arrangement of the laminating member. Therefore, compared to the prior art, the laminating member of the present disclosure can effectively disperse the thermal stress during the subsequent thermal process to avoid the problem of stress concentration and thus to prevent the problem of delamination from occurring to the semiconductor chip.

Furthermore, when the heat dissipating member is provided, even if the height of the package module is not the same as the height of the semiconductor chip, the height above the semiconductor chip and the package module can be leveled by the arrangement of the laminating member and the heat dissipating layer with different thicknesses (with increment), so that the pressure borne by the carrier structure can be distributed more evenly. Therefore, compared to the prior art, the present disclosure may prevent the carrier structure from being broken and prevent the functional chip on the second side from being cracked. Preferably, the arrangement of the functional member increases the overall rigidity of the structure to prevent the carrier structure from being broken and prevent the functional chip from being cracked.

### BRIEF DESCRIPTION OF THE DRAWINGS

FIG. 1A is a schematic cross-sectional view of a conventional semiconductor package.

FIG. 1B is a schematic cross-sectional view of the conventional semiconductor package in a defective condition.

FIG. 2A to FIG. 2F are schematic cross-sectional views illustrating a manufacturing method of an electronic package according to an embodiment of the present disclosure.

FIG. 3 is a schematic cross-sectional view of an electronic package according to another embodiment of FIG. 2F.

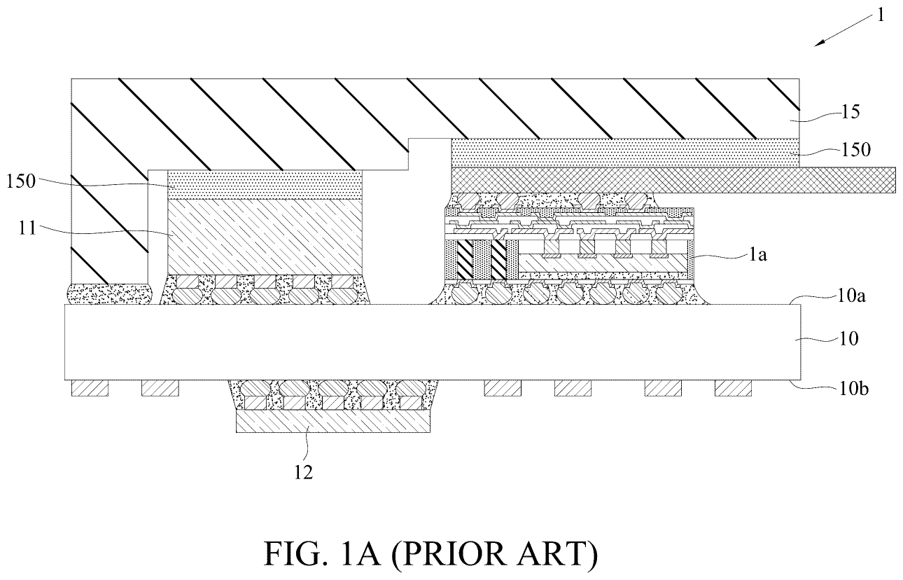

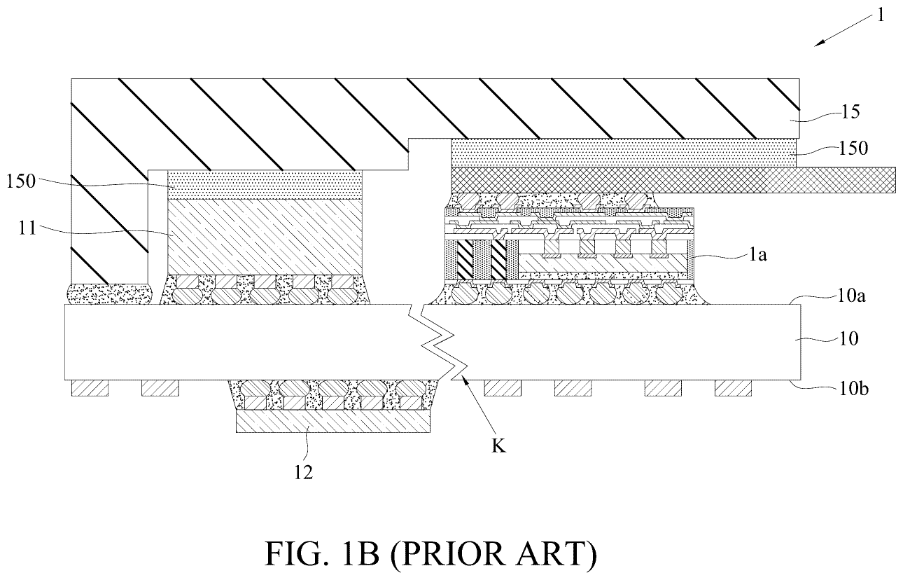

### DETAILED DESCRIPTION

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “upper,” “first,” “second,” “a,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

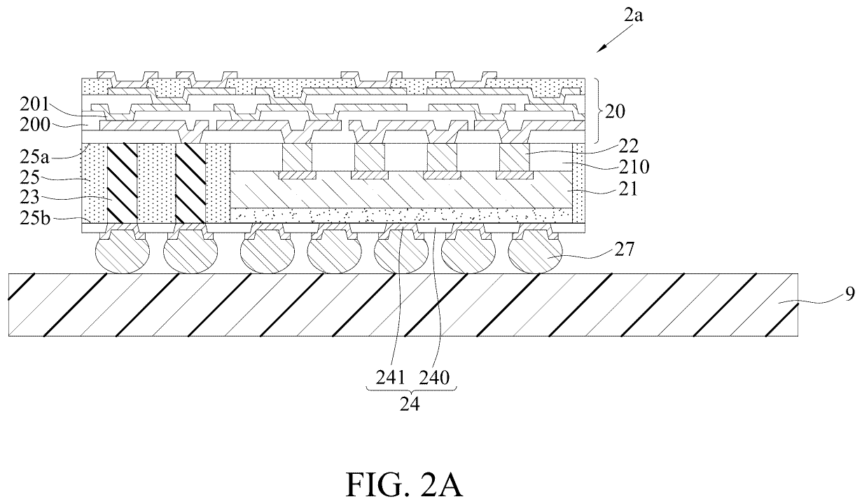

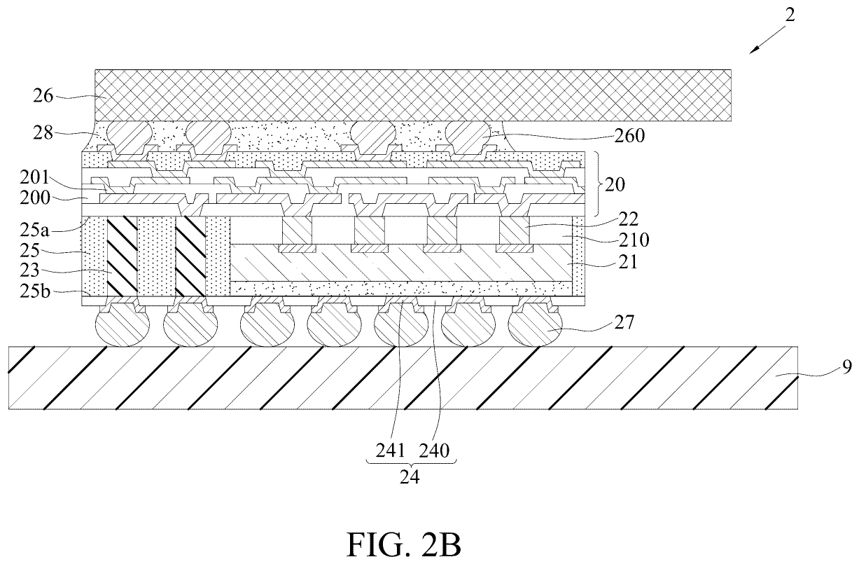

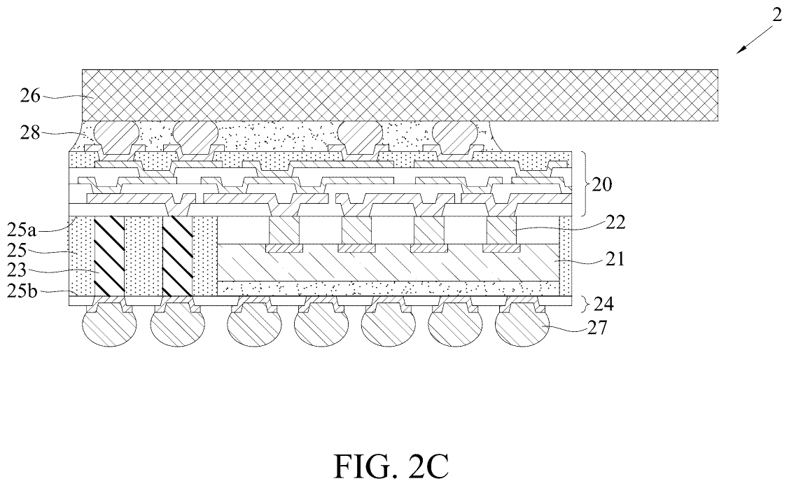

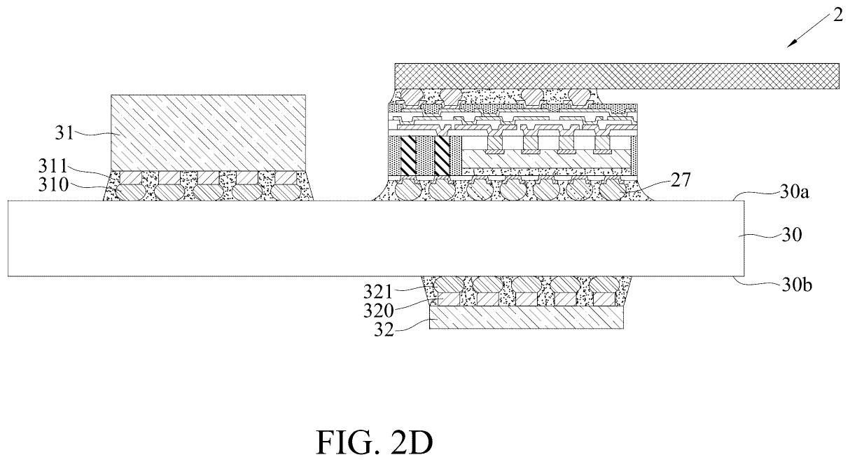

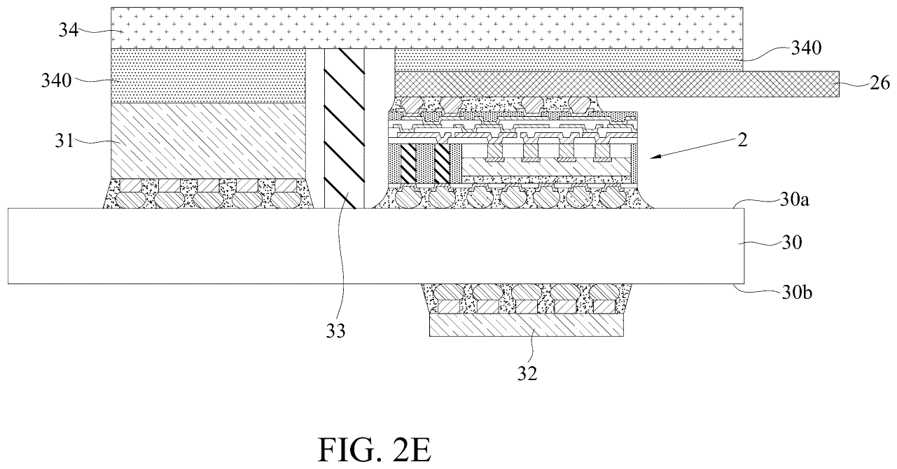

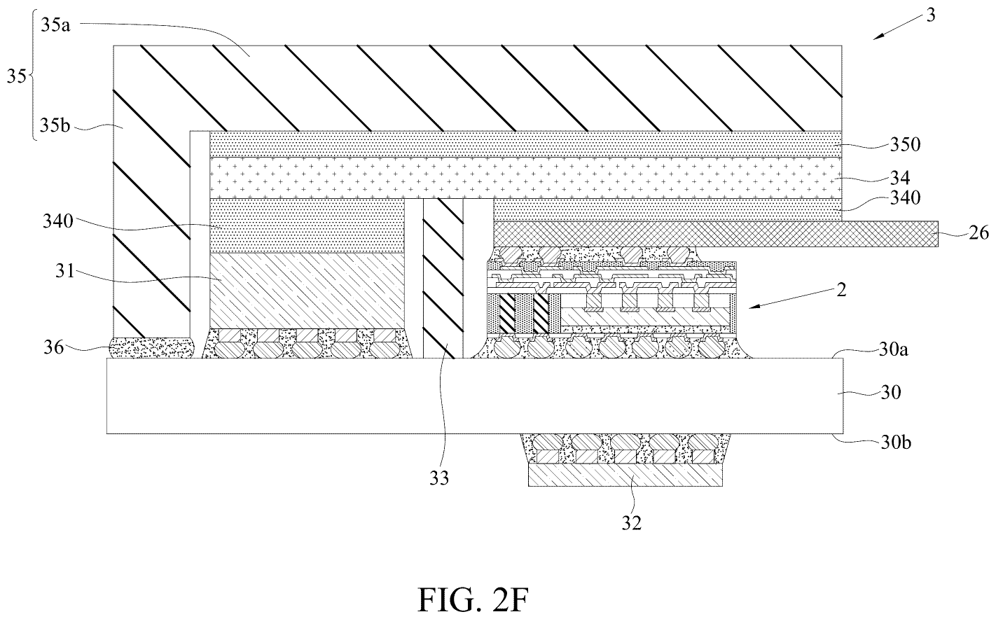

FIG. 2A to FIG. 2F are schematic cross-sectional views illustrating a manufacturing method of an electronic package 3 according to the present disclosure.

As shown in FIG. 2A, an electronic module 2a is provided on a carrier 9. The electronic module 2a includes an encapsulating layer 25, at least one electronic component 21, a plurality of conductive pillars 23, a circuit structure 20, a wiring structure 24, and a plurality of conductive components 27.

The encapsulating layer 25 has a first surface 25a and a second surface 25b opposite to the first surface 25a.

In an embodiment, the encapsulating layer 25 is made of insulating material such as polyimide (PI), dry film, epoxy molding colloid, or epoxy molding compound. For example, the encapsulating layer 25 may be formed by process such as liquid molding, injection, laminating, or compression molding.

The electronic component 21 is embedded in the encapsulating layer 25. A plurality of conductors 22 are bonded to and electrically connected to the electronic component 21. The electronic component 21 is an active component, a passive component, or a combination of the active component and the passive component. The active component is, for example, a semiconductor chip, and the passive component is, for example, a resistor, a capacitor, or an inductor.

In an embodiment, the electronic component 21 is a semiconductor chip with a protection film 210. The protection film 210 is made of, for example, passivation material, and covers the conductors 22.

Further, the conductors 22 are, for example, but are not limited to, conductive circuits, spherical conductors such as solder balls, post-shaped metal conductors such as copper posts, solder bumps, etc., or stud-shaped conductors made by a wire bonding machine.

The conductive pillars 23 are embedded in the encapsulating layer 25 and are made of metallic material such as copper or made of solder material.

The circuit structure 20 is disposed on the first surface 25a of the encapsulating layer 25 and is electrically connected to the conductive pillars 23 and the conductors 22.

In an embodiment, the circuit structure 20 includes a plurality of dielectric layers 200 and a plurality of circuit layers 201 formed on the plurality of dielectric layers 200, and the circuit structure 20 is of, for example, a redistribution layer (RDL) specification. The outermost dielectric layer 200 may serve as a solder-resist layer, and the outermost circuit layer 201 is exposed from the solder-resist layer to serve as electrical contact pads. Alternatively, the circuit structure 20 may include only a single dielectric layer 200 and a single circuit layer 201.

Further, the circuit layer 201 is made of copper. The dielectric layer 200 is made of dielectric material such as polybenzoxazole (PBO), polyimide (PI), or prepreg (PP), or made of solder-resist material such as solder mask or ink.

The wiring structure 24 is disposed on the second surface 25b of the encapsulating layer 25 and is electrically connected to the plurality of conductive pillars 23.

In an embodiment, the wiring structure 24 includes at least one insulation layer 240 and at least one wiring layer 241 formed on the at least one insulation layer 240, and the wiring structure 24 is of, for example, a redistribution layer (RDL) specification. The outermost insulation layer 240 may serve as a solder-resist layer, and the outermost wiring layer 241 is exposed from the solder-resist layer to serve as electrical contact pads.

Further, the wiring layer 241 is made of copper. The insulation layer 240 is made of dielectric material such as polybenzoxazole (PBO), polyimide (PI), or prepreg (PP), or made of solder-resist material such as solder mask or ink.

The conductive components 27 are solder balls or metal bumps (such as copper bumps), and are disposed on the electrical contact pads of the wiring structure 24 and electrically connected to the wiring layer 241.

As shown in FIG. 2B, at least one optical communication component 26 is disposed on the circuit structure 20 to form a package module 2. The optical communication component 26 protrudes from a side surface of the encapsulating layer 25, and the protruding portion of the optical communication component 26 serves as a connection portion for connecting a bus having cables (e.g., optical fiber).

In an embodiment, the optical communication component 26 is a multifunctional integrated chip having an optoelectronic portion, such as a photodiode, for converting an optical signal into an electrical signal, and having a laser portion, such as a laser diode, for converting an electrical signal into an optical signal and emitting optical signals, such as laser signals.

Further, the optical communication component 26 is electrically connected to the electrical contact pads of the circuit layer 201 via a plurality of conductive bumps 260, such as solder bumps, copper bumps, or the like.

A packaging material 28, such as an underfill, may be formed between the circuit structure 20 and the optical communication component 26 to encapsulate the conductive bumps 260.

As shown in FIG. 2C, the carrier 9 is removed.

As shown in FIG. 2D, at least one semiconductor chip 31 and the package module 2 are attached to a carrier structure 30 via the conductive components 27.

In an embodiment, the carrier structure 30 is in the form of a substrate, such as a package substrate with a core layer or a coreless package substrate. Alternatively, the carrier structure 30 may be in the form of other board, such as a lead frame, wafer, or other carrier board with metal routings, without being limited to as such.

Further, the carrier structure 30 has a first side 30a and a second side 30b opposite to the first side 30a, such that the semiconductor chip 31 and the package module 2 are disposed on the first side 30a of the carrier structure 30 and electrically connected to the carrier structure 30, and the second side 30b of the carrier structure 30 can be provided with at least one functional chip 32 electrically connected to the carrier structure 30 as needed.

Based on functional requirements, the semiconductor chip 31 may also be provided with at least one clock and data recovery (CDR) circuit for the optical communication component 26 to provide a serial communication technology, such as serializer/deserializer (SERDES), for recovery or removal of signals in simultaneous clocks and acting as high bandwidth transmission input/output contacts (I/Os). For example, the semiconductor chip 31 may be electrically connected to the carrier structure 30 via a plurality of conductive bumps 310 in a flip-chip manner, and the conductive bumps 310 may be covered by an underfill 311.

In addition, based on functional requirements, the functional chip 32 may be provided with a power management integrated circuit (power management IC) to manage the power supply for the main system. For example, the functional chip 32 may be electrically connected to the carrier structure 30 via a plurality of conductive bumps 320 in a flip-chip manner, and the conductive bumps 320 may be covered by an underfill 321.

It should be appreciated that there are many ways of electrically connecting the semiconductor chip 31 and the functional chip 32, such as wire bonding, which are not limited to the above.

As shown in FIG. 2E, a laminating member 34 is formed on the semiconductor chip 31 and the package module 2, and the optical communication component 26 protrudes from a side surface of the laminating member 34.

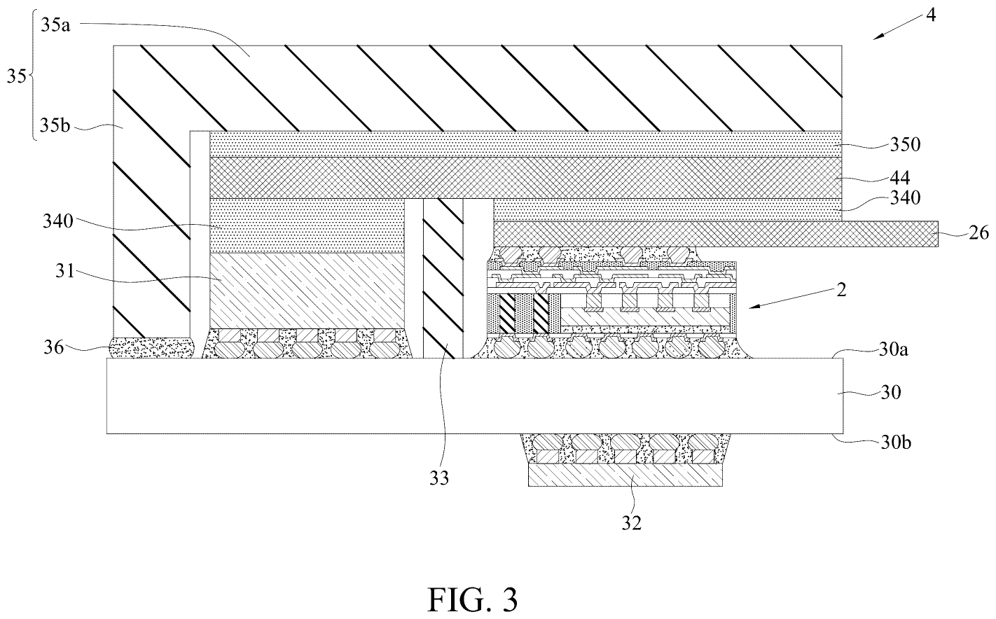

In an embodiment, the laminating member 34 is a platform structure made of glass or other rigid material and is bonded to the semiconductor chip 31 and the package module 2 by means of a heat dissipating layer 340. The heat dissipating layer 340 is made of thermal interface material (TIM), such as highly thermally conductive metallic adhesive material. In another embodiment, as shown in FIG. 3, the laminating member 44 may be a mesh platform structure.

Further, at least one functional member 33, such as a copper pillar or other heat dissipating material pillar, may be disposed on the first side 30a of the carrier structure 30 and connected to the laminating member 34 to contact and support the laminating member 34 as needed.

As shown in FIG. 2F, a heat dissipating member 35 is disposed on the first side 30a of the carrier structure 30 and the laminating member 34 to form the electronic package 3.

In an embodiment, the heat dissipating member 35 is bonded to the laminating member 34 via a heat dissipating layer 350. The heat dissipating layer 350 is made of thermal interface material (TIM), such as highly thermally conductive metallic adhesive material.

Further, the heat dissipating member 35 has a heat dissipating body 35a and at least one supporting leg 35b at a lower side of the heat dissipating body 35a. The heat dissipating body 35a is of a heat sink type and contacts the heat dissipating layer 350 with the lower side, and the supporting leg 35b is bonded to the first side 30a of the carrier structure 30 via an adhesive material 36. In addition, the optical communication component 26 may optionally protrude from a side surface of the heat dissipating body 35a.

Therefore, the manufacturing method of the present disclosure mainly utilizes the arrangement of the laminating member 34 to uniformly distribute the stress of the electronic package 3. Therefore, compared with the prior art, the laminating member 34 is able to effectively disperse the thermal stress during the subsequent thermal process to avoid the problem of stress concentration, and thus to prevent the problem of delamination from occurring to the semiconductor chip 31. Preferably, by adding the functional member 33, the stress of the electronic package 3 can be distributed more evenly to prevent the problem of delamination from occurring to the semiconductor chip 31.

Furthermore, when the heat dissipating member 35 is provided, even if the height of the package module 2 and the height of the semiconductor chip 31 are not the same, the height above the semiconductor chip 31 and the package module 2 can be leveled by the arrangement of the laminating member 34 and the heat dissipating layer 340 with different thicknesses (with increment) between the laminating member 34 and the package module 2 and between the laminating member 34 and the semiconductor chip 31, so that the pressure borne by the carrier structure 30 can be distributed more evenly. Therefore, the carrier structure 30 can be prevented from being broken, and the functional chip 32 on the second side 30b can be prevented from being cracked. Preferably, the arrangement of the functional member 33 increases the overall rigidity of the structure to prevent the carrier structure 30 from being broken and the functional chip 32 from being cracked.

The present disclosure further provides an electronic package 3, 4, which comprises: a carrier structure 30, at least one package module 2, at least one semiconductor chip 31, at least one laminating member 34, 44, and at least one heat dissipating member 35.

The carrier structure 30 has a first side 30a and a second side 30b opposite to the first side 30a.

The package module 2 is disposed on the first side 30a of the carrier structure 30 and electrically connected to the carrier structure 30.

The semiconductor chip 31 is disposed on the first side 30a of the carrier structure 30 and electrically connected to the carrier structure 30.

The laminating member 34, 44 is disposed on the semiconductor chip 31 and the package module 2.

The heat dissipating member 35 is disposed on the first side 30a of the carrier structure 30 and on the laminating member 34.

In an embodiment, the laminating member 34, 44 is a glass structure or a mesh structure.

In an embodiment, the laminating member 34, 44 is a platform structure.

In an embodiment, the laminating member 34, 44 is bonded to the semiconductor chip 31 and the package module 2 via a heat dissipating layer 340.

In an embodiment, the heat dissipating member 35 is bonded to the laminating member 34, 44 via a heat dissipating layer 350.

In an embodiment, the heat dissipating member 35 has a heat dissipating body 35a and at least one supporting leg 35b connecting to the heat dissipating body 35a. The heat dissipating body 35a is bonded to the laminating member 34, 44 via the heat dissipating layer 350, and the supporting leg 35b is bonded to the first side 30a of the carrier structure 30 via an adhesive material 36.

In an embodiment, the electronic package 3 further comprises at least one functional chip 32 disposed on the second side 30b of the carrier structure 30.

In an embodiment, the electronic package 3 further comprises at least one functional member 33 disposed on the first side 30a of the carrier structure 30. The functional member 33 is, for example, a pillar. Alternatively, the functional member 33 is a heat dissipater/dissipator.

In conclusion, the electronic package of the present disclosure and the manufacturing method thereof are configured to distribute the stress of the electronic package uniformly by the arrangement of the laminating member and to increase the overall structural rigidity by the arrangement of the functional member to avoid the problem of stress concentration and thus to prevent the problem of delamination from occurring to the semiconductor chip.

Furthermore, when the heat dissipating member is provided, even if the height of the package module is not the same as the height of the semiconductor chip, the height above the semiconductor chip and the package module can be leveled by the arrangement of the laminating member and the heat dissipating layer with different thicknesses (with increment), so that the pressure borne by the carrier structure can be more even. Thus, the present disclosure can prevent the problem of breaking from occurring to the carrier structure, which in turn prevents the problem of cracking from occurring to the functional chip on the second side.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An electronic package, comprising:
a carrier structure having a first side and a second side opposite to the first side;
a package module disposed on the first side of the carrier structure and electrically connected to the carrier structure;
a semiconductor chip disposed on the first side of the carrier structure and electrically connected to the carrier structure;
a laminating member disposed on the semiconductor chip and the package module; and
a heat dissipating member disposed on the first side of the carrier structure and on the laminating member.

2. The electronic package of claim 1, wherein the laminating member is a glass structure or a mesh structure.

3. The electronic package of claim 1, wherein the laminating member is a platform structure.

4. The electronic package of claim 1, wherein the laminating member is bonded to the semiconductor chip and the package module via a heat dissipating layer.

5. The electronic package of claim 1, wherein the heat dissipating member is bonded to the laminating member via a heat dissipating layer.

6. The electronic package of claim 1, wherein the heat dissipating member has a heat dissipating body and a supporting leg connecting to the heat dissipating body, the heat dissipating body is bonded to the laminating member via a heat dissipating layer, and the supporting leg is bonded to the first side of the carrier structure via an adhesive material.

7. The electronic package of claim 1, further comprising a functional chip disposed on the second side of the carrier structure.

8. The electronic package of claim 1, further comprising a functional member disposed on the first side of the carrier structure and connected to the laminating member.

9. The electronic package of claim 8, wherein the functional member is a pillar.

10. The electronic package of claim 8, wherein the functional member is a heat dissipater.

11. A method of manufacturing an electronic package, comprising:
providing a carrier structure having a first side and a second side opposite to the first side;
disposing a package module and a semiconductor chip on the first side of the carrier structure and electrically connecting the package module and the semiconductor chip to the carrier structure;
disposing a laminating member on the semiconductor chip and the package module; and
disposing a heat dissipating member on the first side of the carrier structure and on the laminating member.

12. The method of claim 11, wherein the laminating member is a glass structure or a mesh structure.

13. The method of claim 11, wherein the laminating member is a platform structure.

14. The method of claim 11, wherein the laminating member is bonded to the semiconductor chip and the package module via a heat dissipating layer.

15. The method of claim 11, wherein the heat dissipating member is bonded to the laminating member via a heat dissipating layer.

16. The method of claim 11, wherein the heat dissipating member has a heat dissipating body and a supporting leg connecting to the heat dissipating body, the heat dissipating body is bonded to the laminating member via a heat dissipating layer, and the supporting leg is bonded to the first side of the carrier structure via an adhesive material.

17. The method of claim 11, further comprising disposing a functional chip on the second side of the carrier structure.

18. The method of claim 11, further comprising disposing a functional member on the first side of the carrier structure and connecting the functional member to the laminating member.

19. The method of claim 18, wherein the functional member is a pillar.

20. The method of claim 18, wherein the functional member is a heat dissipater.
